(19) United States
(12) Patent Application Publication
(10) Pub. No.: US 2023/0067357 A1
(43) Pub. Date: Mar. 2, 2023

(54) INDIVIDUALLY PLASMA-INDUCED MEMORY UNIT CELLS FOR A CROSSBAR ARRAY

(71) Applicant: International Business Machines Corporation, Armonk, NY (US)

(72) Inventors: Soon-Cheon Seo, Glenmont, NY (US); Youngseok Kim, Upper Saddle River, NJ (US); Injo Ok, Loudonville, NY (US); Alexander Reznicek, Troy, NY (US)

(21) Appl. No.: 17/460,827

(22) Filed: Aug. 30, 2021

(51) Int. Cl. H01L 27/24; H01L 45/00

(52) U.S. Cl. CPC H01L 27/2463; H01L 45/08; H01L 45/16

(57) ABSTRACT

An approach to provide a semiconductor structure for an array of individual memory cells forming a crossbar array. A plurality of individual memory cells where each memory cell on a first metal layer includes a top electrode contact and a bottom electrode contact in a second metal layer. The crossbar array includes a word line above each of the individual memory cells connecting one or more adjacent top electrode contacts and a bit line above each of the individual memory cells connecting one or more of the adjacent bottom electrode contacts where each memory cell of the plurality of memory cells has a pre-formed conductive filament in a resistive switch device in each memory cell.

### BACKGROUND OF THE INVENTION

The present invention relates generally to the field of semiconductor memory device technology and more particularly to resistive random-access memory devices.

Resistive random-access memory (ReRAM or RRAM) is a type of non-volatile (NV) random-access (RAM) computer memory that works by changing the resistance or changing the resistance across a dielectric solid-state material, often referred to as a memristor. A conventional RRAM consists of a dielectric material sandwiched between two electrodes.

RRAM formation is based on the concept that a dielectric material, which is normally insulating, can be made to conduct through a filament or conduction path formed in the dielectric material after the application of a sufficiently high voltage. RRAM device operation typically uses the change of resistance that occurs under the application of the applied electric field for RRAM device switching. Resistance switching has been observed in a variety of oxides, but binary metal oxides are typically preferred as a switching material for non-volatile memory applications primarily due to their compatibility with the complementary metal-oxide-semiconductor (CMOS) processing.

Creating an RRAM device for resistive switching typically involves generating oxygen vacancies, typically created at oxide bond locations, where the oxygen has been removed. The oxygen vacancies charge and drift under applied electric fields. The motion of the oxygen ions and vacancies in the oxide can be analogous to the motion of electrons and holes in a semiconductor material. A conduction path or a filament can arise from different mechanisms, including vacancy or metal defect migration. Typically, once the filament in the dielectric material is formed, the filament may be reset or broken. The reset or breaking of the filament in the dielectric material results in high resistance. The filament can be set or re-formed by another voltage or applied electric field, resulting in a lower resistance in the dielectric material. In some cases, many current paths, rather than a single filament, can be involved in typical RRAM applications.

### SUMMARY

Embodiments of the present invention provide an array of individual memory cells forming a crossbar array. The crossbar array includes a plurality of individual memory cells that are on a first metal layer where each of the individual memory cells has a top electrode contact and a bottom electrode contact in a second metal layer. The crossbar array includes a word line above each of the individual memory cells connecting one or more adjacent top electrode contacts and a bit line above each of the individual memory cells connecting one or more of the adjacent bottom electrode contacts.

Embodiments of the present invention provide a method of forming a plurality of memory cell devices in a crossbar array of memory cell devices. The method includes forming a plurality of memory cell devices, where each memory cell device is formed on a portion of a first metal layer and has a bottom electrode contact and a top electrode contact formed in a second metal layer. The method includes performing a plasma process on each of the plurality of top electrode contacts and each of the plurality of bottom electrode contacts in each memory cell where the plasma process creates a conductive filament in a resistive switch device in each memory cell. The method includes using a dual damascene process to form a plurality of second vias in a deposited layer of an interlayer dielectric material and a plurality of word lines and a plurality of bit lines in a third metal layer.

### BRIEF DESCRIPTION OF THE DRAWINGS

The above and other aspects, features, and advantages of various embodiments of the present invention will be more apparent from the following description taken in conjunction with the accompanying drawings.

FIG. 1 is a three-dimensional isometric view of a structure for a resistive switch device and a via on a portion of a first metal layer in accordance with an embodiment of the present invention.

FIG. 2 is a three-dimensional isometric view of the structure of a memory cell with a top electrode contact over the resistive switch device and a bottom electrode contact above the via in accordance with an embodiment of the present invention.

FIG. 3 is a cross-sectional view of the structure through the X-X section of the semiconductor structure of FIG. 2 in accordance with an embodiment of the present invention.

FIG. 4 is a cross-sectional view of the structure through the Y-Y section of the semiconductor structure of FIG. 2 in accordance with an embodiment of the present invention.

FIG. 5 is a three-dimensional isometric view of a portion of an array of the memory cells in accordance with an embodiment of the present invention.

FIG. 6 is a three-dimensional isometric view of a portion of a crossbar array of the memory cells that are connected using a plurality of connection links in a metal layer above each of the memory unit cells in accordance with an embodiment of the present invention.

FIG. 7 is a cross-sectional view of the crossbar array of FIG. 6 through the X-X section in accordance with an embodiment of the present invention.

FIG. 8 is a cross-sectional view of the crossbar array of FIG. 6 through the Y-Y section in accordance with an embodiment of the present invention.

FIG. 9 depicts a flow chart listing representative fabrication steps for a method of forming the crossbar array of FIG. 6 in accordance with an embodiment of the present invention.

### DETAILED DESCRIPTION

Embodiments of the present invention recognize that typical forming voltages for resistive random-access memory (ReRAM, or RRAM) devices utilizing dielectric materials, such as a hafnium oxide can be in the three to three and a half voltage range which is above the required forming voltage for advanced RRAM device technologies with 14 nm or less feature size. In advanced RRAM devices, the desired forming voltages are in the two-volt range or less for the electroforming process to create a conductive filament in the RRAM device. Embodiments of the present invention recognize that an emerging method of forming the conductive filament in a typical crossbar array of connected RRAM devices employs a plasma process to induce a charging voltage to form the conductive bridge or conductive filament in the RRAM devices. Embodiments of the present invention recognize the plasma process produces an antenna effect on the RRAM device that has been shown to form conductive filaments or pre-form conductive filaments with less than two volts of forming voltage in RRAM devices with hafnium oxide dielectric materials.

Embodiments of the present invention recognize that when the plasma process is applied on electrodes of a conventional crossbar array of connected RRAM devices not all of the individual resistive switches or RRAM devices create a conductive filament at the same time. When one or more of the RRAM devices in a conventional crossbar array form a conductive filament ahead of the other RRAM devices in the crossbar array, the first formed conductive filaments can shunt the remaining forming voltage generated by the plasma process through the first forming conductive filaments in the one or more RRAM devices that that first form a conductive filament. Embodiments of the present invention recognize that in this case, conductive filaments may not be formed in some of the remaining RRAM devices.

Embodiments of the present invention recognize that an ability to form a conductive filament in each of the RRAM devices in a crossbar array of RRAM devices is desirable. Embodiments of the present invention recognize that a method and a semiconductor structure to form a crossbar array of RRAM devices using a plasma treatment to lower the forming voltage and that forms a conductive filament in each RRAM device in the crossbar array would be beneficial.

Embodiments of the present invention provide a structure and method of forming the structure for a crossbar array of individual memory unit cells that have a pre-formed conductive filament in each of the resistive switch devices in the individual memory unit cells before the individual memory unit cells are connected in the crossbar array. Embodiments of the present invention provide individual memory unit cells on a first metal layer with top electrode contacts and bottom electrode contacts in a second metal layer, where each of the individual memory unit cells are not connected during the plasma process that forms the conductive filaments in each of the individual memory unit cells. The crossbar array is formed after the individual memory unit cells are plasma treated to form the conductive filament in each of the resistive switch devices.

Embodiments of the present invention provide a crossbar array composed of word lines and bit lines that are formed in a third metal layer above the individual memory unit cells. The crossbar array of word lines and bit lines are formed in a third metal layer after the plasma process. The word lines and the bit lines connect adjacent memory unit cells with a pre-formed conductive filament.

Embodiments of the present invention provide individual memory unit cells where each individual memory unit cell includes a resistive switch device and a via on a portion of a first metal layer and a top electrode contact in a second metal layer that is above and connected to each resistive switch device in each of the individual memory cells and a bottom electrode contact in the second metal layer that is above and connected to a via on the first metal layer (e.g., the Mx metal layer). Each of the individual memory unit cells are connected by vias on one of a top electrode contact or a bottom electrode contact in the second metal layer (e.g., the Mx+1 metal layer) to lines in a third metal layer (e.g., the Mx+2 metal layer) above the memory unit cells.

Embodiments of the present invention provide a crossbar array composed of a plurality of lines in the Mx+2 metal above and connected to individual memory unit cells. Embodiments of the present invention provide bit lines in the Mx+2 metal layer that form a portion of the crossbar array over the individual memory unit cells. The bit lines are connected to more than one adjacent bottom electrode contacts in the Mx+1 metal layer by the via formed on each of the top electrode contacts. The word lines in the Mx+2 metal layer of the crossbar array connect by vias to more than one adjacent top electrode contacts in the Mx+1 metal layer. The bit lines run in one direction and the word lines run in a perpendicular direction to the bit lines in the crossbar array. The bit lines can run parallel to other bit lines connecting the bottom electrode contacts and the word lines can run parallel to other word lines in the crossbar array of RRAM devices.

Embodiments of the present invention provide a method of forming a crossbar array of a plurality of individual memory unit cells each memory unit cell includes a portion of the Mx metal layer with a resistive switch device and a via on the portion of the Mx metal layer and a top electrode contact and a bottom electrode in a second metal layer (e.g., Mx+1 metal layer) that are connected to the portion of the Mx metal layer by the via. A conductive filament is formed using a plasma process on the top and bottom electrode contacts of unconnected individual memory unit cells prior to forming the crossbar array of word and bit lines in the third metal layer (e.g., Mx+2 metal layer).

Embodiments of the present invention provide a method of creating a plurality of individual memory unit cells on a portion of a first or the Mx metal layer by forming a resistive switch device and a via on a portion of the Mx metal layer. In an embodiment, an interlayer dielectric is deposited and a top electrode contact is formed over the resistive switch device and bottom electrode contact is formed in the Mx+1 metal layer over the via on the first metal layer.

Embodiments of the present invention provide a method of forming top electrode contacts and bottom electrode contacts with a large metal surface area. The top electrode contacts and the bottom electrode contacts are exposed to the plasma process to induce an antenna effect. The plasma process, using the antenna effect, generates a forming voltage that forms or pre-forms the conductive filament in the resistive switch device in each memory unit cell. Embodiments of the present invention provide an exposed top surface area of the top electrode contact that is at least 1.2 times larger than the top surface area of the bottom electrode contact. Ideally, the surface area of the top electrode is maximized within the allowed area of the grid or array of the individual memory cells and the surface area of the bottom electrode is minimized in order to enhance the antenna effect of the plasma process. When the plasma process is applied, each of the memory unit cells are not connected and each of the top electrode contacts and bottom electrode contacts are not connected.

Embodiments of the present invention provide the method where the conductive filament is formed by a plasma process that is applied on the exposed top surfaces of the top and bottom electrode contacts of each memory unit cell in an array of many memory unit cells prior to creating the crossbar array of word lines and bit lines. In other words, the plasma process is applied to the top surfaces of the bottom electrode contacts and the top electrode contacts of each of the individual, unconnected memory unit cells.

Since each of the individual memory unit cells with a resistive switch device are not connected to each other during the plasma process then, if a conductive filament forms first in one of the individual memory unit cells during the plasma process, the plasma generated forming or charging voltage would not shunt through the first filament-forming resistive switch device (i.e., RRAM device). In this way, embodiments of the present invention provide a plurality of individual memory unit cells where after the plasma process, each of the individual memory units cells has a resistive switch device with a conductive filament that is formed during the plasma process.

Embodiments of the present invention provide a crossbar array that is formed after the plasma process forms the conductive filaments in the resistive switch devices in each of the individual memory unit cells. The crossbar array is by creating a plurality of word lines and bit lines in the Mx+2 metal layer. The plurality of word lines and bit lines forming the crossbar connect by a plurality of vias the bottom electrode contacts and the top electrode contacts in the second metal layer. Each via connects to one of the lines to one of the top electrode contacts or the bottom electrode contacts of an adjacent memory unit cell. Each of the lines contact at least two vias to join at least two adjacent top electrode contacts or at least two adjacent bottom electrodes in one or more adjacent memory unit cells.

Detailed embodiments of the claimed structures and methods are disclosed herein. The method steps described below do not form a complete process flow for manufacturing integrated circuits, such as semiconductor devices. The present embodiments can be practiced in conjunction with the integrated circuit fabrication techniques currently used in the art, for RRAM devices forming a crossbar array, and only so much of the commonly practiced process steps are included as are necessary for an understanding of the described embodiments. The figures represent cross-section portions of a RRAM device after fabrication and are not drawn to scale, but instead are drawn to illustrate the features of the described embodiments. Specific structural and functional details disclosed herein are not to be interpreted as limiting, but merely as a representative basis for teaching one skilled in the art to variously employ the methods and structures of the present disclosure. In the description, details of well-known features and techniques may be omitted to avoid unnecessarily obscuring the presented embodiments.

References in the specification to “one embodiment”, “other embodiment”, “another embodiment”, “an embodiment”, etc., indicate that the embodiment described may include a particular feature, structure, or characteristic, but every embodiment may not necessarily include the particular feature, structure or characteristic. Moreover, such phrases are not necessarily referring to the same embodiment. Further, when a particular feature, structure, or characteristic is described in connection with an embodiment, it is understood that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “over”, “on”, “positioned on”, or “positioned atop” mean that a first element is present on a second element wherein intervening elements, such as an interface structure, may be present between the first element and the second element. The term “direct contact” means that a first element and a second element are connected without any intermediary conducting, insulating or semiconductor layers at the interface of the two elements.

In the interest of not obscuring the presentation of the embodiments of the present invention, in the following detailed description, some of the processing steps, materials, or operations that are known in the art may have been combined for presentation and for illustration purposes and in some instances may not have been described in detail. Additionally, for brevity and maintaining a focus on distinctive features of elements of the present invention, description of previously discussed materials, processes, and structures may not be repeated with regard to subsequent Figures. In other instances, some processing steps or operations that are known may not be described. It should be understood that the following description is rather focused on the distinctive features or elements of the various embodiments of the present invention.

Deposition processes as used herein include but are not limited to chemical vapor deposition (CVD), plasma vapor deposition (PVD), electroplating, ionized plasma vapor deposition (iPVD), atomic layer deposition (ALD), and plasma-enhanced chemical vapor deposition (PECVD).

As known to one skilled in the art, typical BEOL processes discussed herein include dual damascene, single damascene, and subtractive metal etching processes. Dual damascene process is most commonly used for BEOL patterning and metallization processes. A dual damascene process typically includes patterning via and trench in a dielectric material, such as an interlayer dielectric and filling the via holes and trenches with a layer of metal and planarizing the metal using a chemical mechanical (CMP) process to remove overburden or excess metal. The single damascene process includes patterning via holes in a first dielectric material, filling the via holes with a deposited metal layer, and then preforming a CMP to remove overburden or excess metal and then depositing a second dielectric material and then, performing a second etch process to form trenches, filling the trenches with metal layers and then performing a CMP to remove the overburden of metal layers. In some embodiments, a subtractive metallization process is used where a metal layer is deposited, patterned, etched, and a dielectric material is deposited over the top surface. A CMP exposes the top surface of the patterned metal.

Patterning processes discussed herein include but are not limited to one of lithography, photolithography, an extreme ultraviolet (EUV) lithography process, or any other known semiconductor patterning process that is followed by one or more of the following etching processes discussed below.

Etching processes discussed herein to remove portions of material as patterned or masked by the lithography process includes etching processes, such as dry etching process using a reactive ion etch (RIE), or ion beam etch (IBE), a wet chemical etch process, or a combination of these etching processes and is not limited to these etching processes.

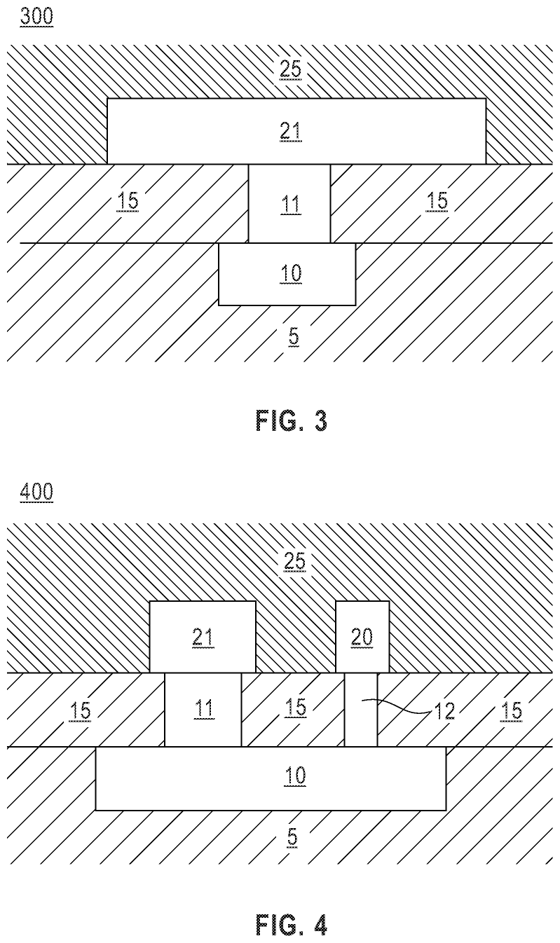

FIG. 1 is a three-dimensional isometric view of structure 100 for resistive switch device (RSD) 11 and via 12 on Mx metal 10 in accordance with an embodiment of the present invention. Structure 100 depicts only a portion of the Mx metal layer. As depicted, FIG. 1 includes RSD 11, and via 12 above Mx metal 10. Not depicted in FIG. 1 is an interlayer dielectric (ILD) surrounding Mx metal 10. For example, ILD 5 depicted in FIG. 3 may surround the sides of Mx metal 10 and ILD 15 can surround the sides of RSD 11 and via 12.

Mx metal 10 may be a portion of any metal layer formed in the back end of the line (BEOL) of a semiconductor chip or in a portion of a metal layer formed in the middle of the line (MOL) of a semiconductor chip. After Mx metal 10 is formed with known metallization processes and CMP, in an embodiment, a SiN, a SiCN material, or a similar material (not depicted) may be deposited on Mx metal 10 as a cap. Mx metal 10 may be composed of, but is not limited to typical BEOL metals, which include Cu, Cu—Mn, W, Ru, or Co. The width of Mx metal 10 is greater than the width of RSD 11. The length of Mx metal 10 may be two to five times the width of RSD 11 but, is not limited to these lengths.

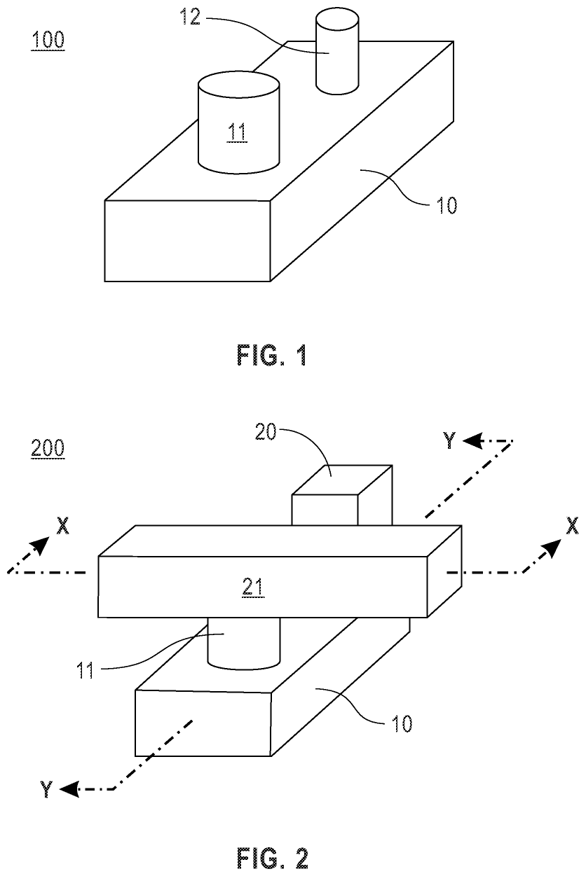

RSD 11 can be created using known RRAM device formation processes. In various embodiments, RSD 11 includes a bottom electrode on Mx metal 10, a switching layer, and top electrode metal. The bottom electrode, the switching layer, and the top electrode of RSD 11 are not depicted in FIG. 1. As known to one skilled in the art, a switching layer is a dielectric material capable of exhibiting the non-volatile resistance switching with an applied electric field or applied voltage and generates oxygen vacancies and allows oxygen ions to migrate to form conductive filament or filaments between two electrodes from the bottom to the top electrode or vice versa. Dielectric materials for the switching layer include but not limited to, such as a hafnium oxide (e.g., HfO₂), a silicon dioxide, titanium oxide, a tantalum oxide, a tungsten oxide, a cerium oxide, another rare earth oxide, or combination of these materials. The bottom electrode can be composed of but not limited to TaN, TiN, Ru, W, and any metal or metal alloy suitable for RRAM devices. In some embodiments, the top electrode metal can be Ti-rich TiN, TiN, TiN with TaN, or any metal layer which promotes conductive filament formation in the switching layer. In various embodiments, a conductive filament may be formed in the switching layer in RSD 11 during a plasma process as discussed later with respect to FIG. 2.

A width of RSD 11 may range from 10 to 1000 nanometers but is not limited to these widths. RSD 11 is patterned using known lithography processes, such as photolithography and etched, for example using a reactive ion etching (RIE) plasma process.

In various embodiments, via 12 is formed using conventional or damascene via formation processes that includes depositing a dielectric material, patterning the dielectric material using lithography, and etching the dielectric material (e.g., using RIE) to form a hole for via 12 followed by a via metal deposition and planarization using a CMP. Via 12 can be formed with any conductive material used for vias in memory devices. For example, via 12 may be composed of copper or tungsten but is not limited to these metals.

In another embodiment, via 12 is formed using a dual damascene process that creates via 12 together with top electrode contact (TEC) 21 and bottom electrode contact (BEC) 20 (not depicted in FIG. 1) after depositing a layer of ILD over RSD 11 and the exposed portions of Mx metal 10. The ILD is patterned and etched forming holes and trenches. A metal layer is deposited in via holes for vias 12 and trenches for BEC 20 and TEC 21. A CMP of the deposited metal for vias 12 and TEC 21 removes excess metal or overburden (e.g., after CMP the top surface of the ILD is level with the top surface of BEC 20).

FIG. 2 is a three-dimensional isometric view of structure 200 with TEC 21 over RSD 11 and BEC 20 above via 12 (not visible in FIG. 2) in accordance with an embodiment of the present invention. FIG. 2 includes the elements of FIG. 1 and TEC 21 and BEC 20, where via 12 (not visible) is under BEC 20. Dielectric materials, such as ILD 5, ILD 15 and ILD 25 are not depicted in FIG. 2 to provide a clear view of the elements of structure 200. Via 12 (not visible in FIG. 2) connects Mx metal 10 to BEC 20. FIG. 2 illustrates a location of cross-section X-X and cross-section Y-Y of structure 200 depicted in FIGS. 3 and 4, respectively. Structure 200 depicted in FIG. 2 can form a single memory cell.

In an embodiment, using a subtractive process after forming structure 100 depicted in FIG. 1, a layer of metal (e.g., Mx+1 metal layer) is deposited on exposed top surfaces of RSD 11, via 12, and ILD 15 (depicted in FIG. 3). The layer of metal may be composed of suitable BEOL metals used in subtractive metallization processes. The BEOL metals for subtractive metallization include but are not limited to W, Ru, or Al. The BEOL metal for the Mx+1 metal layer can be deposited and patterned using known lithography and etched to form BEC 20 and TEC 21. Not depicted in FIG. 2, an interlayer dielectric material may be deposited and chemical mechanical polish (CMP) can be performed to expose top surfaces of BEC 20 and TEC 21.

In other embodiments, using a single damascene process, a layer of ILD (e.g., ILD 25 in FIG. 3) is deposited over RSD 11, ILD 15, and via 12. ILD 25 can be patterned and etched to form trenches for TEC 21 and BEC 20 using lithography and RIE. Examples of BEOL metal materials that can be suitable for damascene processes include but are not limited to Cu, Cu—Mn, or W with another appropriate barrier metal liner. The trenches may be lined with one or more appropriate barrier layers then, the trenches can be filled with one of the BEOL metal materials. The overburden layer or the excess BEOL metal material is removed by using a CMP. In these embodiments, ILD 25 stops at the top surface of TEC 21 and BEC 20 exposing the surfaces of TEC 21 and BEC 20 (not depicted in FIG. 3).

In yet another embodiment, via 12, BEC 20, and TEC 21 are formed using the dual damascene process. In this embodiment, via 12 is not formed in FIG. 1. An ILD, such as ILD 25 (not depicted) can be deposited over RSD 11 and over the dielectric surrounding RSD 11 (not depicted). The ILD is patterned and etched, for example using lithography and RIE to form via holes for vias 12 and trenches for BEC 20 and TEC 21. A BEOL metal which is suitable for a damascene process, such but not limited to Cu, Cu—Mn, or W with appropriate barrier layers can be deposited in the trenches and via holes to form BEC 20, TEC 21, and via 12. A CMP removes the overburden or excess of BEOL metal material. In this case, the CMP levels the ILD (not depicted in FIG. 2) and exposes the top surfaces of TEC 21 and BEC 20.

As depicted in FIG. 2, the area of the top surface of TEC 21 is larger than the area of the top surface of BEC 20. The magnitude of the difference in the top surface areas of TEC 21 and BEC 20 varies according to the materials used in RSD 11. For example, the amount by which the area of the top surface of TEC 21 is larger than the area of the top surface of BEC 20 is dependent on the metal oxide present in RSD 11. In various embodiments, the area of the top surface of TEC 21 is greater than 1.2 times greater than the area of the top surface of BEC 20.

For the purposes of the present invention, hereinafter, structure 200 is called memory cell 200. Memory cell 200 is composed of Mx metal 10, RSD 11, via 12, TEC 21, and BEC 20. In various embodiments, memory cell 200 is a RRAM device with electrode contacts (e.g., BEC 20 and TEC 21). The RRAM device is modified from a conventional RRAM device to include the electrode contacts that are in the Mx+1 metal layer that is directly above Mx metal 10. The electrode contacts, such as BEC 20 and TEC 21 each contact one of via 12 or RSD 11 on Mx metal 10, respectively. Each of memory cells 200 have one via 12, one RSD 11, a TEC 21 with a top surface area that is at least 1.2 times greater than the top surface area of BEC 20 in the memory cell.

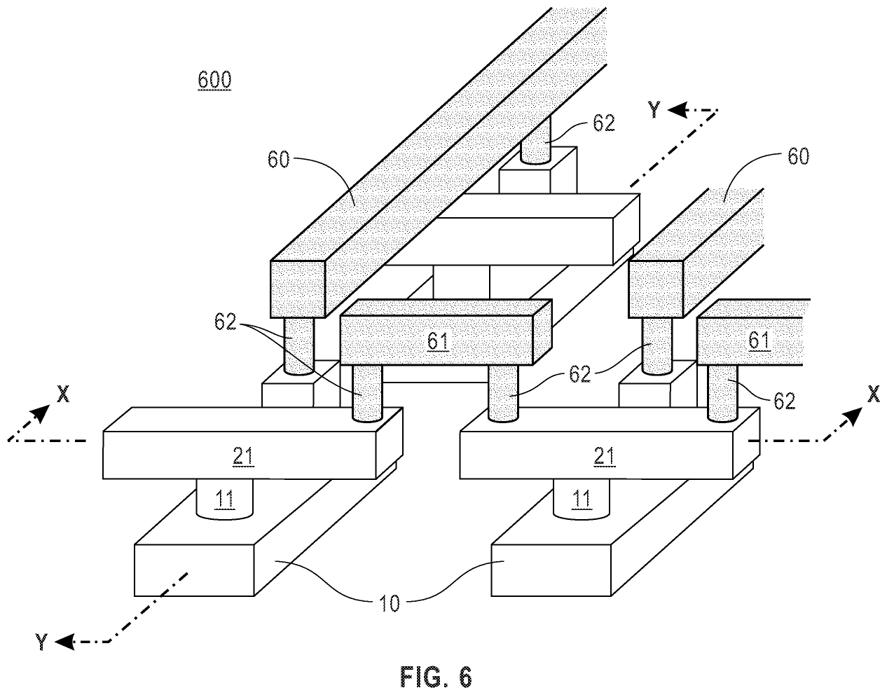

After forming memory cell 200, a plasma process is performed on exposed top surfaces of BEC 20 and TEC 21. In various embodiments, a conductive filament (not depicted) forms in the switching layer (not depicted) of RSD 11 during the plasma process. As previously discussed, the conductive filament may form in the dielectric material of the switching layer of RSD 11 during plasma processing due to the antenna effect when the plasma is applied to TEC 21 and BEC 20. When the plasma process occurs, TEC 21 and BEC 20 collect a charge creating the conductive filaments in RSD 11. For example, the plasma process uses a gas including, but not limited to, argon, nitrogen, hydrogen, helium, xenon, ammonia, or mixtures thereof with a pressure range from 1 mTorr to 3 Torr, and a duration of 5 seconds to 15 minutes but is not limited to these parameters. The plasma process can utilize an inductively coupled plasma (ICP) tool, a capacitively coupled plasma (CCP) tool, or a microwave generated plasma tool. In another embodiment of the present application, an e-beam treatment is performed. The e-beam treatment can include using an electron energy from 0.01 kV to 100 kV, and an electron beam dose of 100 μC/cm² to 5000 μC/cm² but is not limited to these parameters. The plasma process occurs before forming the crossbar array depicted in FIG. 6 (i.e., occurs when each of BEC 20 and TEC 21 is unconnected to other BEC 20 and TEC 21, respectively in other memory cells 200).

FIG. 3 is cross-sectional view 300 of memory cell 200 through in the X-X section of memory cell 200 depicted in FIG. 2 in accordance with an embodiment of the present invention. As depicted, FIG. 3 includes Mx metal 10, RSD 11, ILD 5, ILD 15, ILD 25, and TEC 21 over RSD 11.

If TEC 21 is formed using a subtractive metallization process as depicted in FIG. 3, then ILD 25 covers over TEC 21 after forming TEC 21. Before performing the plasma process, the top surface of ILD 25 should be polished using CMP down to the same level as the top surface of TEC 21. The CMP exposes the top surfaces of TEC 21 and BEC 20 (not depicted in FIG. 3).

If a damascene process is used to form TEC 21 and BEC 20 (not depicted in FIG. 3), then, the height of ILD 25 should the same as the height of TEC 21 (e.g., the top surfaces of ILD 25 and TEC 21 are the same level) after a CMP removes the overburden of metal forming TEC 21.

FIG. 3 depicts the view along the length of TEC 21 over RSD 11. In other examples, TEC 21 may be longer or shorter than depicted in FIG. 3 and the widths of RSD 11 and Mx metal 10 with respect to TEC 21 may be different. In one example, RSD 11 may have a width of 10 to 1000 nm, and TEC 21 may have a length of 20 to 2000 nm but TEC 21 and RSD 11 are not limited to these dimensions.

FIG. 4 is cross-sectional view 400 of memory cell 200 through in the Y-Y section of memory cell 200 depicted in FIG. 2 in accordance with an embodiment of the present invention. As depicted, FIG. 4 includes Mx metal 10, RSD 11, via 12, ILD 5, ILD 15, ILD 25, TEC 21, and BEC 20.

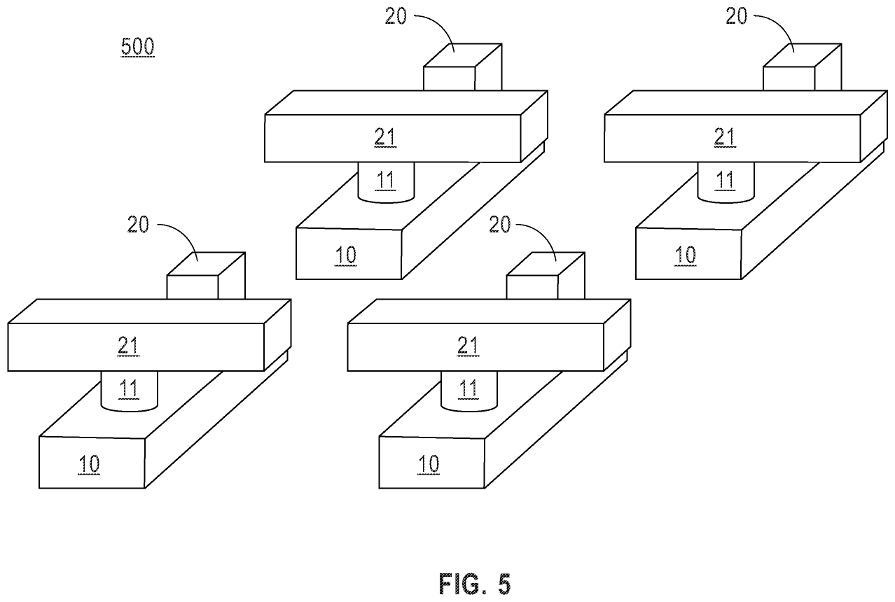

If BEC 20 and TEC 21 are formed using a subtractive metallization process as depicted in FIG. 4, then ILD 25 can be over TEC 21 and BEC 20 as shown in FIG. 4. After depositing ILD 25 over TEC 21 and BEC 20 in FIG. 4, a CMP can be used to remove the top portion of ILD 25 to exposed top surfaces of BEC 20 and TEC 21. After the CMP, the top surfaces of ILD 25, TEC 21, and BEC 20 are level and BEC 20 and TEC 21 exposed. The CMP occurs before the plasma process as discussed with respect to FIG. 5.

If a damascene process is used to form BEC 20 and TEC 21, the height of the deposited ILD 25 should be the same as the height as the exposed surfaces of TEC 21 and BEC 20 after using a CMP to remove the overburden or excess BEOL metal deposited in the trenches etched in ILD 25 to form BEC 20 and TEC 21.

FIG. 4 depicts a length of Mx metal 10 along cross-section Y-Y and the width of TEC 21 and length of BEC 20 along cross-section Y-Y. In other examples, the length of Mx metal 10, length of BEC 20, the width of TEC 21, via 12, and RSD 11, and the relative lengths and widths of these elements with respect to each other may vary according to the application, the materials used, and a metal layer in which memory cell 200 resides. As known to one skilled in the art, feature sizes in higher metal layers are typically larger.

FIG. 5 is a three-dimensional isometric view of a portion of array 500 of a plurality of memory cells 200 in accordance with an embodiment of the present invention. As depicted, FIG. 5 includes four evenly spaced memory cells 200 in an array or a grid. As depicted in FIG. 5, each of memory cells 200 are composed of one RSD 11 that include a conductive filament after the plasma process, Mx metal 10, vias 12, BEC 20, and TEC 21. The four memory cells 200 are not connected during plasma processes (e.g., each of BEC 20 and TEC 21 in each memory cell 200 are not connected to a BEC 20 or a TEC 21 in another memory cell 200).

Any number of memory cells 200 can be formed for the array of memory cells 200 depicted in FIG. 5. Array 500 in other examples can be an array of forty memory cells 200 (not depicted). In some embodiments, memory cells 200 have the same space or distance between them in one direction but the space or distance between them is different in different directions. In other words, each of memory cells 200 are evenly spaced in the X-direction with a first spacing and are evenly spaced in the Y-direction in a second spacing that is different than the x direction spacing.

In FIG. 5, each memory cell of memory cells 200 in the array are evenly spaced. For example, each of memory cells 200 are the same distance apart from each other in both the identified X-X and Y-Y cross-sections depicted in FIG. 6 that are perpendicular to each other. In some embodiments, memory cells 200 in the array have a different spacing in the perpendicular directions along the length of Mx metal 10 and the width of Mx metal 10. For example, the spacing between each of memory cells 200 through the length of Mx metal 10 is greater than the spacing between memory cells 200 along the width of Mx metal 10. In other embodiments, the number of memory cells 200 in the array depicted in FIG. 5, the size of each memory cell 200, and the space between each of memory cells 200 can vary according to the semiconductor chip application, electrical performance, and materials selected for RSD 11.

In various embodiments, the array of memory cells 200 are formed simultaneously. In other words, each of the processes to form each of RSD 11 occurs at once and each of the processes to form each of via 12 occur at the same time, etc. Similarly, the processes to form each of BEC 20 and TEC 21 in the metal layer above vias 12 and RSD 11 occur at the same time.

Once array 500 of the individual memory cells 200 depicted in FIG. 5 is formed, the plasma process or plasma treatment induces a lower forming voltage to pre-form the conductive filament in RSD 11. For example, as previously discussed, when using a hafnium oxide dielectric, such as HfO₂ in RSD 11, using the plasma process on the top surfaces of TEC 21 and BEC 20 forms a conductive filament in each RSD 11 in each of memory cells 200 in array 500. Applying the plasma process discussed in detail previously with respect to FIG. 2 to the top surfaces of each TEC 21 and each BEC 20 in array 500 of individual memory cells 200 allows conductive filament formation to occur independently in each memory cell 200 (e.g., each conductive filament forms independent of the other memory cells 200 in array 500). After performing the plasma process, each RSD 11 in each of memory cells 200 can have a conductive filament in the switching layer (not depicted).

As previously discussed, when a conventionally formed crossbar array of connected memory cells is plasma treated to form conductive filaments in each of the resistive switch devices in a conventionally formed crossbar array, if one of the resistive switch devices are connected in the conventional crossbar array of memory cells forms a conductive filament before the other resistive switch devices, then the plasma generated antenna voltage to form conductive filaments may be shunted through this early conductive filament-forming resistive switch device. In this case, the desired conductive filaments may not form in the other remaining resistive switch devices in the conventionally formed crossbar array structure.

However, when applying the plasma process to each of the individual memory cells 200 in array 500 that are not connected, if one of RSD 11 forms a conductive filament ahead of the rest of RSDs 11 in array 500, then the plasma process in the other memory cells 200 continues to form the conductive filaments in the other memory cells 200 since they are not connected.

By performing the plasma processes on BEC 20 and TEC 21 of each of individual memory cells 200 that are not connected ensures that a conductive filament is formed in each RSD 11 in each memory cell 200 since the voltage generated by the plasma process cannot be shunted to one RSD 11 in array 500 since each RSD 11 in array 500 is not connected to another RSD 11 and therefore, the plasma process generated voltage is applied to each unconnected RSD 11 in array 500 to form a conductive filament in each RSD 11 of array 500.

FIG. 6 a three-dimensional isometric view of a portion of crossbar array 600 of a plurality of memory cells 200 connected using a plurality of connection links 60 and connection links 61 formed in a metal layer above each of memory cells 200 in accordance with an embodiment of the present invention. As depicted, FIG. 6 includes the elements of FIG. 5 and vias 62, connection links 60 and connection links 61, where connection links 60 and connection links 61 may be one of word lines or bit lines residing in a metal layer above BEC 20 and TEC 21. One or more dielectric materials or ILD (not depicted in FIG. 6) can surround the sides and exposed top surfaces of Mx metal 10, RSD 11, vias 12, BEC 20, TEC 21, vias 62, and connection links 60 and connection links 61. The dielectric materials are not depicted in FIG. 6 so that the view of the elements of crossbar array 600 is not obstructed.

In various embodiments, vias 62, connection links 60 and connection links 61 are formed using conventional dual damascene processes (e.g., ILD deposit, ILD pattern, ILD etch, BEOL metal deposit, and CMP) to form vias 62, connection links 60 and connection links 61. In this case, vias 12, connection links 60, and connection links 61 can be formed after the plasma process is performed on each of BEC 20 and TEC 21 (e.g., forms the conductive filament in each RSD 11 in each of memory cells 200). Vias 62 provide an electrical connection from one of BEC 20 or TEC 21 to one of connection links 60 or connection links 61, respectively to form crossbar array 600.

In various embodiments, connection link 60 provides a connection from one BEC 20 in one of memory cells 200 to a BEC 20 in an adjacent memory cell of memory cells 200. As depicted in FIG. 6, connection link 60 can extend along a row of memory cells 200 in crossbar array 600 to connect a series of BEC 20 in adjacent memory cells 200. As depicted, connection link 60 can be a line or a portion of a metal layer extending in the Y direction to connect a number of BEC 20 to each other through connection link 60. In other words, connection link 60 connects a number of memory cells 200 through connection link 60, vias 62, and BEC 20. In an embodiment, one connection link 60 connects two adjacent memory cells 200. While FIG. 5 depicts two of connection link 60, any number of connection link 60 connecting any number of memory cells 200 can be present in other embodiments. In some embodiments, each of connection link 60 is a bit line.

In various embodiments, one of connection links 61 provides a connection from one TEC 21 in one of memory cells 200 to another TEC 21 in an adjacent memory cell of memory cells 200 as depicted in FIG. 6. For example, one of connection links 61 can extend along a row of memory cells 200 in crossbar array 600 to connect a series of TEC 21 in adjacent memory cells 200. As depicted in FIG. 6, connection links 61 can be a line or portions of a metal layer extending in the X direction to connect a number of TEC 21 to each other through at least one of connection links 61. In other words, connection link 61 connects a number of memory cells 200 through connection links 61, vias 62, and TEC 21. In other embodiments, any number of connection links 61 connecting any number of memory cells 200 can be formed in crossbar array 600. As depicted, the lines forming connection links 60 and connection links 61 are perpendicular to each other. In an embodiment, each of connection links 60 is a word line or a portion of a word line.

As depicted, connection links 60 using vias 62, BEC 20, and vias 12 (not visible in FIG. 6) connects Mx metal 10 and RSD 11 in one or more adjacent memory cells 200 and connection links 61 using vias 62, TEC 21 connects RSD 11 in one or more adjacent memory cells 200 to form crossbar array 600. Crossbar array 600 is formed after plasma processes so that each of memory cells 200 independently form a conductive filament during plasma processes (i.e., there is no shunting of charging voltage through one or two RSD 11 with early filament formation during plasma treatment). In some embodiments, connection links 60 and connection links 61 are formed together with vias 62 using a dual damascene process.

Each of connection links 60 and connection links 61 may connect any number of memory cells 200. For example, connection link 60 may connect two memory cells 200 or may connect twenty or more memory cells 200. In various embodiments, connection links 60 and connection links 61 connect the same number of memory cells 200 to form crossbar array 600. In some embodiments, connection links 60 and connection links 61 each connect a different number of memory cells 200 in crossbar array 600. For example, connection links 60 connects twenty memory cells 200, and connection links 61 connects thirty memory cells 200.

FIG. 7 is a cross-sectional view 700 through the X-X section of crossbar array 600 of FIG. 6 in accordance with an embodiment of the present invention. As depicted by the location of X-X in FIG. 6, cross-sectional view 700 is taken from the very first row of crossbar array 600. Cross-sectional view 700 does not show the X-X cross-section of connection link 60 which should appear in between connection link 61 in other different locations of the X-X cross-sectional view. For example, if the cross-sectional view is taken from the next row of crossbar array 600 or another row beyond the first row depicted in FIG. 7, X-X cross-section of connection link 60 should appear between two adjacent connection links 61.

As depicted, FIG. 7 includes Mx metal 10, ILD 5, ILD 15, ILD 25, ILD, 35, ILD 45, RSD 11, TEC 21, and vias 62 connecting to connection link 61. In various embodiments, connection link 61 is a word line in the metal layer (e.g., the Mx+2 metal layer) above TEC 21. For example, connection link 61 may be in the Mx+2 metal layer while TEC 21 is in the Mx+1 metal layer, and Mx metal 10 in the Mx metal layer. In FIG. 7, ILD 45 surrounds exposed surfaces connection link 61, ILD 35 surrounds via 62 and is over TEC 21, while ILD 15 surrounds RSD 11. As depicted, Mx metal 10 is surrounded by ILD 5. ILD 5, ILD 15, ILD 25, ILD 35, and ILD 45 can be the same or different dielectric materials used for an interlayer dielectric. As depicted in FIG. 7, a connection link 61 contacts two vias 62, and each of the two vias 62 connect to a TEC 21 in one of two memory cells 200. In other embodiments, one or more of connection link 61 connects more than two memory cells 200 using vias 62. In some embodiments, connection link 61 connects to more than two of memory cells 200. In various embodiments, connection link 61 is a word line. As depicted in FIG. 6, each of a plurality of connection links 61 are parallel to and above each of memory cells 200 in the X-X direction depicted in FIG. 6. In other examples, the number of memory cells 200 connected by connection link 61 is different and the spacing between each of TEC 21, connection link 61 and/or Mx metal 10 is different.

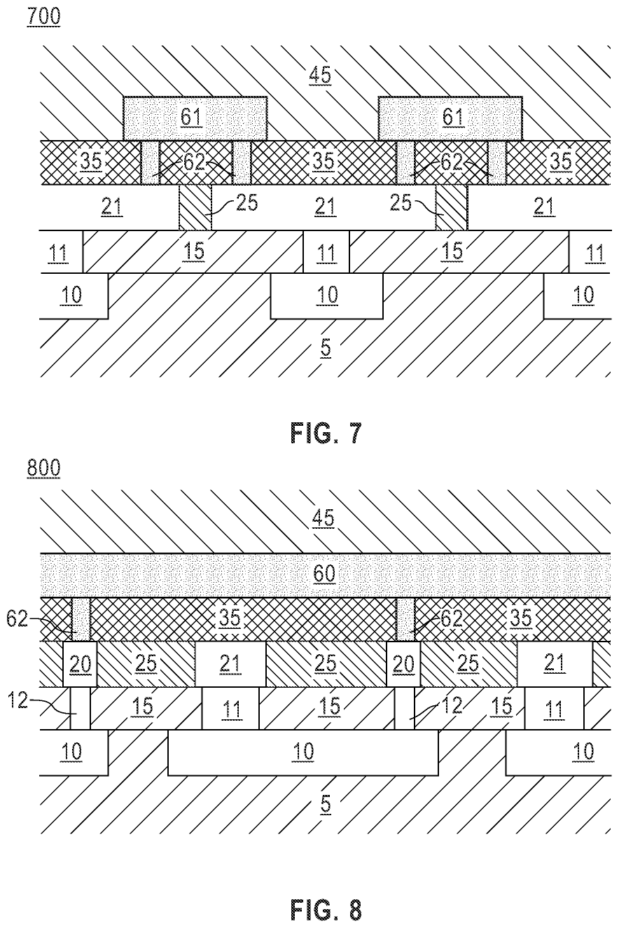

FIG. 8 is a cross-sectional view of crossbar array 600 through the Y-Y section of crossbar array 600 of FIG. 6 in accordance with an embodiment of the present invention. As depicted, FIG. 8 includes ILD 5, ILD 15, ILD 25, ILD 35, ILD 45, Mx metal 10, RSD 11, TEC 21, BEC 20, vias 62 connecting to connection link 60. In various embodiments, connection link 60 is a bit line in the metal layer (e.g., the Mx+2 metal layer) above BEC 20. As depicted, ILD 35 is under connection link 60 and surrounds via 62. As depicted in FIG. 7, Mx metal 10 connects through via 12 to BEC 20 in the Mx+1 metal layer which is connected to connection link 60 in the Mx+2 metal layer by a via 62. In various embodiments, each of connection links 60 is a bit line that connects to two or more of memory cells 200. In FIG. 8, connection links 60 run parallel to and above each of memory cells 200 in the Y-Y direction. In other examples, three or more BEC 20 connect to one of connection links 60 through three of more vias 62 (one of vias 62 connecting to each BEC 20.

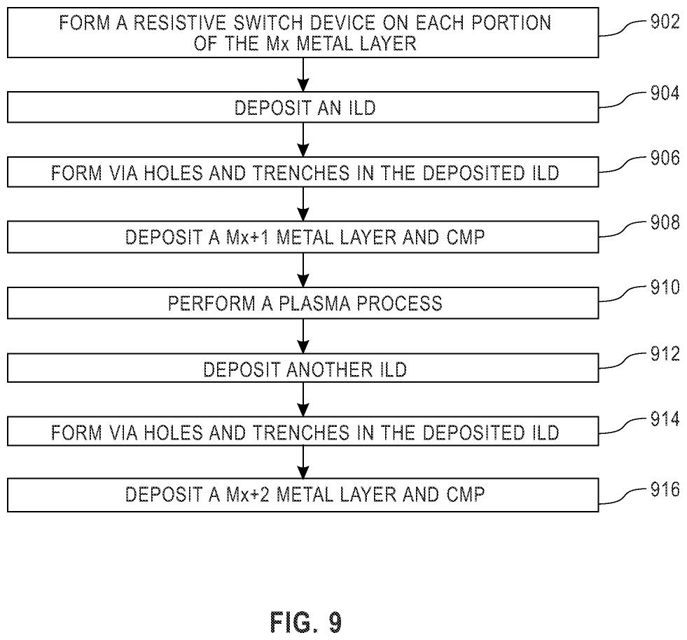

FIG. 9 depicts a flow chart listing representative fabrication steps for a method of forming a crossbar array of RSD 11 in accordance with an embodiment of the present invention. As depicted, FIG. 9 includes a representation of the significant steps in a process to form a crossbar array of RSD 11 with a pre-formed conductive filament. A dual damascene process is used in FIG. 9 to form vias, top electrode contacts, word and bit lines. However, as known to one skilled in the art, in other embodiments, other processes, such as a subtractive metallization process or a single damascene process may form one or more of vias, top electrode contacts, word or bit lines.

In step 902, the method includes forming a resistive switch device on each portion of the Mx metal layer (e.g., Mx metal 10 in FIG. 1). The portion of the Mx metal layer is in a previously deposited ILD. As discussed in detail with respect to FIG. 1, a resistive switch device (e.g., RSD 11) is formed with known RRAM formation processes for forming the resistive switch device on each portion of the Mx metal layer. The resistive switch device can be formed by depositing a bottom electrode on the portion of the Mx metal layer, depositing a switching layer composed of a dielectric material, and depositing a top electrode using known semiconductor deposition processes, such as chemical vapor deposition (CVD), physical vapor deposition (PVD), or another deposition process. The bottom electrode layer, the switching layer, and the top electrode are patterned and etched, for example, by RIE to form the resistive switch device on the portion of the Mx metal layer. In some embodiments, the resistive switch device can be formed with other layers or materials.

In step 904, the method includes depositing an interlayer dielectric material (ILD). This can be the first deposited ILD (e.g., ILD 15 in FIG. 7). The ILD material can be deposited with any known ILD deposition processes, such as PVD can include but is not limited to SiO₂, SiCOH, or another dielectric or interlayer (ILD) material used in semiconductor manufacturing. ILD layer is then planarized with a CMP.

In step 906, the method includes forming via holes and trenches in the deposited ILD using a dual damascene process. The patterning and etching of the deposited ILD may occur using photolithography and RIE. An ILD patterning and etching, for example with RIE of the deposited ILD forms the via holes on each portion of the Mx metal layer and the trenches that will electrode contacts later in step 908.

In step 908, the method includes depositing a BEOL metal material. A layer of a BEOL metal material is deposited over the structure (e.g., over the exposed surface of the ILD and portions of the Mx metal layer). The BEOL metal material, such as Cu or W can be deposited in each of the via holes and trenches. A CMP of the deposited BEOL metal material completes the formation of one or more vias on the portion of the Mx metal layer and a plurality of top and bottom electrode contacts in the Mx+1 metal layer.

In step 910, the method includes performing a plasma process to form a conductive filament in the dielectric material in each of the resistive switch devices (e.g., RSD 11). The plasma process discussed in detail with respect to FIG. 2 is applied to the exposed top surfaces the bottom electrode contact (e.g., BEC 20 and TEC 21 in FIG. 5. The plasma process may use a gas including, but not limited to, argon, nitrogen, hydrogen, helium, xenon, ammonia or mixtures thereof. The plasma process is applied the individual memory cells (e.g., memory cells 200 as depicted in FIG. 2) that are not yet connected to each other (i.e., each of BEC 20 and TEC 21 are not connected to another electrode contact in another memory cell).

In step 912, the method includes depositing another ILD over the structure (e.g., over the exposed portions of the previously deposited or first ILD and the remaining portions of the Mx+1 metal layer (e.g., over the exposed top surfaces of the top and bottom electrode contacts depicted as TEC 21 and BEC 20 in FIG. 5). In various embodiments, a CMP is not needed since the top surface is already flat.

In step 914, the method includes forming via holes and trenches in the most recently deposited or a second ILD using the dual damascene process. Via holes and trenches are patterned and etched in the second ILD.

In step 916, the method includes depositing a BEOL metal material for the Mx+2 metal layer over exposed surfaces of the second ILD and the exposed portions of the Mx+1 metal layer (e.g., BEC 20 and TEC 21 depicted in FIG. 6). The BEOL metal material deposited for the Mx+2 metal layer fills the via holes on the Mx+1 metal layer and the trenches in the second ILD. A CMP removes excess BEOL metal material from the top surfaces to complete the formation of the vias, word lines, and bit lines (e.g., vias 62, connection links 60 and connection links 61, respectively, as depicted in FIG. 6). In other embodiments, one of a subtractive process or a repeated single damascene process can be used to form the vias, word, or bit lines. After forming the vias, word lines, and bit lines, another layer of ILD can be deposited over exposed top surfaces of the second ILD, to form more word lines and bit lines in additional BEOL metal layers. Using known semiconductor chip manufacturing process, power planes, interconnections, and contacts can be formed to complete the semiconductor chip.

The flowchart in the figures illustrates the operation of one possible implementation of the methods and device fabrication steps according to various embodiments of the present invention and is not intended to limit the methods to create the embodiments of the present invention. As known to one skilled in the art, the semiconductor structures illustrated in embodiments of the present invention may be created using different methods (e.g., subtractive metallization processes or damascene metallization processes). Furthermore, each block in the flowchart may represent a process or a portion of processes, which comprises one or more fabrication steps for manufacturing the specified device(s). In some alternative implementations, the processes noted in the blocks may occur out of the order noted in the Figures. For example, two blocks shown in succession may, in fact, be executed substantially concurrently, or the blocks may sometimes be executed in the reverse order, depending upon the functionality involved.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

The methods as described herein can be used in the fabrication of integrated circuit chips or semiconductor chips. The resulting semiconductor chips can be distributed by the fabricator in raw wafer form (that is, as a single wafer that has multiple unpackaged chips), as a bare die, or in a packaged form. In the latter case, the semiconductor chip is mounted in a single chip package (such as a plastic carrier, with leads that are affixed to a motherboard or other higher-level carrier) or in a multichip package (such as a ceramic carrier that has either or both of surface interconnections and buried interconnections). In any case, the semiconductor chip is then integrated with other semiconductor chips, discrete circuit elements, and/or other signal processing devices as part of either (a) an intermediate product, such as a motherboard, or (b) an end product. The end product can be any product that includes semiconductor chips, ranging from toys and other low-end applications to advanced computer products having a display, memory, a keyboard or other input device, and a central processor.

What is claimed is:

1. An array of individual memory cells forming a crossbar array, the crossbar array comprising:
a plurality of individual memory cells with a top electrode contact and a bottom electrode contact in an array;
a word line above each of the individual memory cells connecting one or more adjacent top electrode contacts; and
a bit line above each individual memory cell of the plurality of individual memory cells connecting one or more adjacent bottom electrode contacts.

2. The crossbar array of claim 1, wherein the individual memory cells are each a resistive random-access memory device.

3. The crossbar array of claim 1, wherein each of the individual memory cells further comprise:
a portion of a first metal layer, a resistive switch device, and a first via on the portion of the first metal layer;
a bottom electrode contact in a second metal layer connecting to the first via; and
a top electrode contact in the second metal layer over and connecting to the resistive switch device.

4. The crossbar array of claim 1, wherein the top electrode contact has a top surface area that is larger than a top surface area of the bottom electrode contact.

5. The crossbar array of claim 4, wherein the top surface area of the top electrode contact is at least 1.2 times larger than the top surface area of the bottom electrode contact.

6. The crossbar array of claim 1, wherein the individual memory cells are evenly spaced in the array of the individual memory cells.

7. The crossbar array of claim 1, wherein the word line above each of the individual memory cells in a third metal layer connects at least two or more individual memory cells, and wherein a plurality of the word lines composes, at least in part, the crossbar array.

8. The crossbar array of claim 1, wherein the bit line above each of the individual memory cells in a third metal layer connects at least two or more individual memory cells, and wherein a plurality of the bit lines composes, at least in part, the crossbar array.

9. The crossbar array of claim 7, wherein the plurality of the word lines and a plurality of the bit lines are perpendicular to each other.

10. The crossbar array of claim 1, wherein the individual memory cells each include a conductive filament in each memory cell of the plurality of memory cells.

11. A method of forming an array of a plurality of memory cell devices in a crossbar array of memory cell devices, the method comprising:
forming a plurality of memory cell devices, wherein each memory cell device of the plurality of memory cell devices in on a portion of a first metal layer and has a bottom electrode contact and a top electrode contact in a second metal layer;
performing a plasma process on each top electrode contact of a plurality of top electrode contacts and each bottom electrode contact of a plurality of bottom electrode contacts; and
forming a plurality of second vias on the second metal layer and forming a plurality of word lines and a plurality of bit lines in a third metal layer, wherein each second via of the plurality of second vias connects to one of a word line of the plurality of word lines or to a bit line of the plurality of bit lines.

12. The method of claim 11, wherein forming the plurality of memory cell devices further comprises:
forming a plurality of resistive switch devices, wherein each resistive switch device of the plurality of resistive switch devices are on the portion of the first metal layer;
depositing a first interlayer dielectric material; and
forming a plurality of first vias, the plurality of top electrode contacts, and the plurality of bottom electrode contacts using a dual damascene process, wherein the plurality of top electrode contacts and the plurality of bottom electrode contacts are in the second metal layer.

13. The method of claim 11, wherein forming the plurality of second vias on the second metal layer and forming the plurality of word lines and the plurality of bit lines in the third metal layer, further comprises:
depositing a second interlayer dielectric material;
selectively etching the second interlayer dielectric material to form a plurality of via holes and a plurality of trenches;
depositing a third metal layer over exposed surfaces of the plurality of via holes, the plurality of trenches, and the second interlayer dielectric material;
performing a chemical mechanical polish to remove an overburden of the third metal layer to form the plurality of second vias, wherein each second via contacts one of a word line of the plurality of word lines or a bit line of the plurality of bit lines in the third metal layer.

14. The method of claim 12, wherein each resistive device of the plurality of resistive switch devices includes a bottom electrode, a switching layer, and a top electrode.

15. The method of claim 11, wherein performing the plasma process on each of the plurality of top electrode contacts and each of the plurality of bottom electrode contacts occurs before forming the plurality of word lines and the plurality of bit lines that create the crossbar array of the memory cell devices.

16. The method of claim 11, wherein performing the plasma process on each of the plurality of top electrode contacts and each of the plurality of bottom electrode contacts forms a conductive filament in each memory cell of the plurality of memory cells before to forming the crossbar array of the memory cells.

17. The method of claim 12, wherein performing the plasma process on each of the plurality of top electrode contacts and each of the plurality of bottom electrode contacts generates an antenna effect to form a conductive filament in each resistive switch device of the plurality of resistive switch devices.

18. The method of claim 11, wherein performing the plasma process on each of the plurality of top electrode contacts and each of the plurality of bottom electrode contacts further comprises:
using a gas composed of one or more gases from a group of argon, nitrogen, hydrogen, helium, xenon, or ammonia; and
using one tool of a group of an inductively coupled plasma tool, a capacitively coupled plasma tool, or a microwave generated plasma tool.

19. The method of claim 11, wherein the plurality of word lines and the plurality of bit lines are formed perpendicular to each other.

20. The method of claim 11, wherein forming the plurality of word lines and the plurality of bit lines, further comprises each word line of the plurality of word lines connecting at least two adjacent top electrode contacts of the plurality of top electrode contacts.
